(19) United States
(12) Patent Application Publication
(10) Pub. No.: US 2025/0055258 A1
(43) Pub. Date: Feb. 13, 2025

(54) INTELLIGENT PHOTONIC DEVICE HEALTH MANAGEMENT

(71) Applicant: Micron Technology, Inc., Boise, ID (US)

(72) Inventors: Febin Sunny, Folsom, CA (US); Poorna Kale, Folsom, CA (US); Saideep Tiku, Fort Collins, CO (US)

(21) Appl. No.: 18/763,716

(22) Filed: Jul. 3, 2024

Related U.S. Application Data
(60) Provisional application No. 63/519,107, filed on Aug. 11, 2023.

(51) Int. Cl. H01S 5/183

(52) U.S. Cl. CPC H01S 5/18397; H01S 5/18308

(57) ABSTRACT

A photonic probing system, including a communication bus for communicating a main photonic waveguide signal therethrough, a splitter that splits off a portion of the main photonic waveguide signal to create an off-shoot portion photonic signal, a photodetector that converts the off-shoot portion photonic signal to a converted electrical current, a current threshold detector that compares the converted electrical current to a threshold value to determine if the converted electrical current exceeds the threshold value, if the converted electrical current does not exceed the threshold value, then the current threshold detector generates a laser generating signal directed toward a VCSEL, and wherein the laser generating signal drives the VCSEL to generate a laser signal directed toward a central control system.

### PRIORITY INFORMATION

This application claims the benefit of U.S. Provisional Application No. 63/519,107, filed on Aug. 11, 2023, the contents of which are incorporated herein by reference.

### TECHNICAL FIELD

The present disclosure relates generally to apparatuses, non-transitory machine-readable media, and methods associated with intelligent photonic device health management.

### BACKGROUND

Devices having photonic components (a photonic device) can be utilized in many fields of technology. For instance, photonic components find prevalent usage in camera systems used for building security or surveillance. Examples of photonic components that are utilized in such systems include photonic accelerators and/or photonic-on-chip components.

One issue that arises in their use is determining the health of the photonic components. This can be detrimental to such devices as their performance can degrade as the photonic components age. This is due to drift as the operational values that are assumed are being used are drifting away from their target values thereby making the performance of the photonic component less precise. By knowing the aged performance characteristics of a photonic component, its performance can be optimized until the device or component is ultimately replaced.

### BRIEF DESCRIPTION OF THE DRAWINGS

FIG. 1 illustrates an example surveillance system at a facility that utilizes devices with a photonic component in accordance with some embodiments of the present disclosure.

FIG. 2 is a functional block diagram of a photonic probing system for monitoring the health of a device with a photonic component within the system in accordance with some embodiments of the present disclosure.

FIG. 3 is a block diagram of an example computer system in which embodiments of the present disclosure may operate.

FIG. 4 is a flow diagram corresponding to a method of providing photonic device health monitoring in accordance with some embodiments of the present disclosure.

### DETAILED DESCRIPTION

Apparatuses, systems, and methods related to intelligent photonic device health management are disclosed herein. As discussed above, one issue that arises in their use is determining the health of the photonic components. Their performance can degrade as the photonic components age, thereby deteriorating the health of the photonic component. This is, for example, due to drift as the operational values that are assumed are being used by the photonic component are drifting away from their target values thereby making the performance of the photonic component less precise. Another cause of deteriorating photonic device health is the decreasing ability of a device to produce signal strength.

By knowing the aged performance characteristics of a photonic component, its performance can be optimized until the device or component is ultimately replaced. One way to accomplish this is through use of a computing device that can receive device design parameters, operation parameters, and/or throughput characteristics, also referred to herein as device throughput characteristics, corresponding to a photonic component within a device, such as a photonic accelerator component.

One type of device that uses photonic components is a smart power over Ethernet (POE) device. Such devices may contain a photonic accelerator component, photonic on-chip component, and/or off-chip communication. For instance, in some devices, a photonic accelerator is being used to perform video analytics or other computer vision related tasks.

In order to detect aging related characteristics to the photonic components, the smart PoE includes a photonic probing system/module. The components making up the system may be placed on the same chip as the photonic component (e.g., photonic accelerator) or as a separate module.

Waveguides, which carry photonic signals within these photonic components, can have off-shoots created via splitters in a main waveguide. In such embodiments, an off-shoot portion split off of a main waveguide photonic signal, for example, with which the photonic components and NVR components communicate, will traverse an off-shoot waveguide, and this off-shoot photonic signal can be read using a photodetector.

From such an off-shoot photonic signal, characteristics of aging can be sensed and identified. For example, a drop in signal output and/or drift from a selected resonant wavelength are characteristic of aging and both will reflect in reduced power output from the photodetector. The power output can be represented as a total signal density of the main waveguide photonic signal.

The power output can be quantified by measurement (sensing) by a photodiode in the photodetector. The photodiode converts the photonic signal into a current and that current value can then be compared to a threshold current value by a current threshold detector. For example, if the sensed power output (current generated by the photodiode and compared by the current threshold detector) falls below a threshold, it can be determined that corrective measures in tuning the photonic component may be required, such as by adding a photonic signal boost equivalent to the sensed drop in current to compensate for the drop in power output.

To identify this issue with a photonic component, once the current threshold detector detects that a photonic signal is failing to generate the threshold current, a spike signal can be generated from the current threshold detector, which in turn can drive a vertical cavity surface emission laser (VCSEL) to generate a laser pulse, sent to a central control system of the photonic device or component. The VCSEL for each module/component/device can have a specific wavelength assigned to it so that the laser detection component of the central control system can recognize the module/component/device with the aging problem immediately.

An example of an embodiment of the present disclosure can, for example, include a photonic probing system. Such a system can include a communication bus for communicating a main photonic waveguide signal therethrough, a splitter that splits off a portion of the main photonic waveguide signal to create an off-shoot portion photonic signal, a photodetector that converts the off-shoot portion photonic signal to a converted electrical current, a current threshold detector that compares the converted electrical current to a threshold value. This comparison determines whether the converted electrical current exceeds the threshold value. If the converted electrical current does not exceed the threshold value, then the current threshold detector generates a laser generating signal directed toward a VCSEL. The laser generating signal drives the VCSEL to generate a laser signal directed toward a central control system.

A single photonic health management platform may include one or more reconfigurable photonic probing systems as shown in FIG. 2. In such embodiments, these probes can be reconfigurable in the sense that light from multiple photonic devices can be selectively routed to a single probe using photonic shunts. Additionally, the waveguides in this system may carry one or more wavelengths, and so, in some embodiments, the photonic probing system can selectively filter and evaluate one or more of these wavelengths.

In some embodiments, the photonic probing system can be configured to route wavelengths to one or more probes. Embodiments can also include the ability to tune a VCSEL using electrical components post deployment. This allows for the VCSEL to send unique laser signals as different wavelength signals are being evaluated. For example, the splitter may be configured to split off a portion of a first wavelength and the laser signal provides a unique signal known to the central control system to represent the first wavelength. Then, the splitter can be reconfigured to split off a portion of a second wavelength and the laser signal provides a unique signal known to the central control system to represent the second wavelength.

A photonic device can be an edge device. An edge device describes a photonic device that has processing capabilities and that connects and/or exchanges data with other devices and systems over a communications network. For example, edge devices can include Internet of things (IoT) devices and/or user equipment (UE). A UE can include hand-held devices such as a hand-held telephone and/or a laptop computer equipped with a mobile broadband adapter, among other possible devices.

IoT devices can include devices that comprise sensors and which can exchange data collected from said sensors. IoT devices can include smart home devices such as thermostats and doorbells and/or wearable devices such as smart watches, among other possible IoT devices. The edge device can be an end node such as a camera. Edge devices can also include drones having one or more cameras (imaging components), for example. In many instances, the photonic device (e.g., edge device) comprising the photonic accelerator can be a PoE device wherein the device receives its power via an Ethernet connection.

As used herein, a photonic accelerator is hardware that accelerates specific categories of computing in the optical domain to address the growing demands for computing resources and capacity. Photonic accelerators can be utilized to perform matrix multiplication using a plane light conversion method. Mach-Zehnder interferometer method, and/or wavelength division multiplexing method, among others. A photonic accelerator can be utilized to process images captured by a camera, for example. Generally photonic components, such as a photonic accelerator, can be a processing device.

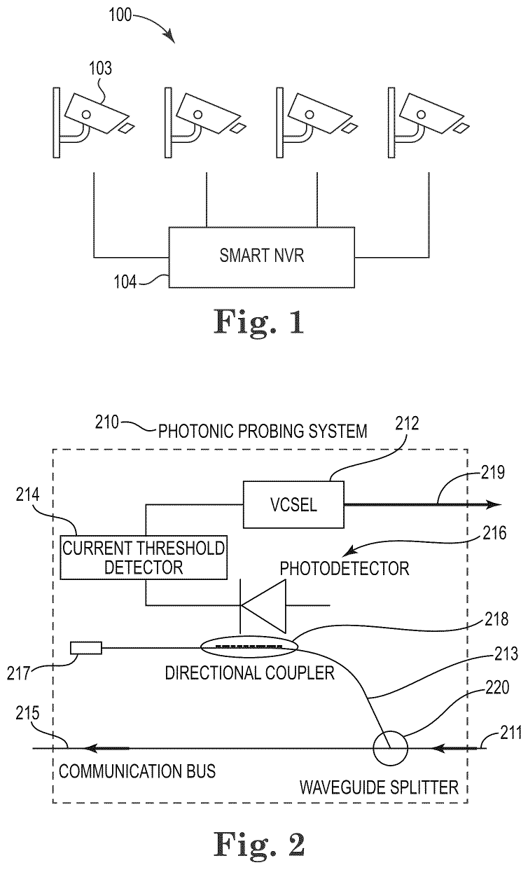

FIG. 1 illustrates an example surveillance system at a facility that utilizes devices with a photonic component in accordance with some embodiments of the present disclosure. The surveillance system 100 includes a number of cameras 103. The cameras 103 are each photonic devices as they include a photonic component, such as a photonic accelerator.

The cameras 103 can be coupled to a network video recorder (NVR) 104 which is a computing device that records data from the cameras 103. The cameras 103 can be powered utilizing one or more PoE components. These PoE camera devices 103 can be coupled to the NVR device 104 such that the camera devices 103 are coupled to the NVR device 104 through the PoE components. The PoE components can provide power to the devices 103 and can route the signals provided by the camera devices 103 to the NVR device. The NVR device can store the signals provided by the camera devices 103 to record data (e.g., video data) provided by the camera devices 103.

The PoE components and/or the NVR device can be referred to herein as smart devices/components given that the PoE components and/or the NVR device can be utilized to gather the device operation parameters of the devices 103. For instance, the PoE components and/or the NVR device can request the device operation parameters from each of the devices 103. Upon receipt of the device operation parameters from the devices 103, the PoE components and/or the NVR device can provide the device operation parameters to a health monitoring computing device connected to or part of the system 100. The PoE components and/or the NVR device can gather the device operation parameters for determining device characteristics that may be adjusted based on photonic component health.

The health monitoring computing device, in addition to receiving the device operation parameters, can access the device design parameters for each of the devices 103. The health monitoring computing device can have previously stored the device design parameters in a memory subsystem of the health monitoring computing device.

To improve the performance or prolong the life of a photonic device or component, photonic aging data can, for example, be used to derive a loss gradient. The loss gradient represents the error between an estimated photonic value (e.g., photonic device/component throughput predictions) and a true photonic value (e.g., photonic device/component throughput characteristics). The loss gradient can be used to add or adjust a weight value (a boost signal that can be applied to the photonic signal to boost photonic device/component throughput) that can be applied to the system to account for the photonic device/component age to improve the performance of the photonic device/component.

In various instances, the processing resource of the system 100 can perform backpropagation using the loss gradient computed using the loss function to add or update a weight applied to the system. The processing resource of the system 100 can generate the loss function to generate the loss gradient. In various instances, the loss function and the backpropagation can be performed by different devices.

The devices 103 can include hardware, firmware, and/or software configured to perform operations utilizing a photonic accelerator. The health monitoring computing device and the devices 103 can further include memory sub-systems (e.g., a non-transitory MRM), on which may be stored instructions (e.g., instructions) and/or data (e.g., configurations).

The devices 103 can include photonic accelerators. The devices 103 can perform measurements to generate the device operation parameters. The edge devices 103, including the processors, can cause the device operation parameters to be generated.

FIG. 2 is a functional block diagram of a photonic probing system for monitoring the health of a device with a photonic component within the system in accordance with some embodiments of the present disclosure. The system 210 includes a communication bus 215 for communication of an optical signal 211 thereon and having a waveguide splitter 220 to split a portion 213 of the signal 211 off that can be used to analyze the health of the photonic component. In the embodiment of FIG. 2, the system 210 receives a main waveguide photonic signal 211 and an off-shoot portion 213 of the signal 211 is split off using the splitter 220. This off-shoot portion 213 can then be analyzed using a number of elements, such as, a directional coupler 218 for directing the off-shoot portion to the other elements, a photodetector 216 for converting the photonic signal 213 to an electrical current, a current threshold detector 214 for determining if the converted current of signal 213 is below a threshold value. The current threshold detector also produces a spike signal if the current is below the threshold. The spike signal is sent to a VCSEL 212 that generates a laser pulse 219 which is sent to the central control system. In some embodiments, the system 210 also includes a receiver 217 for collecting the remnants of the off-shoot signal.

The VCSEL can create a laser pulse 219 at a unique wavelength that identifies, to the central control system, the photonic component/device to which the photonic probing system 210 is connected. For example, if the photonic probing system determines that the power output has fallen below a threshold value, then a current spike can be generated by the current threshold detector 214 and sent to a VCSEL 212. The current spike provides power to drive the VCSEL 212 to create a laser signal.

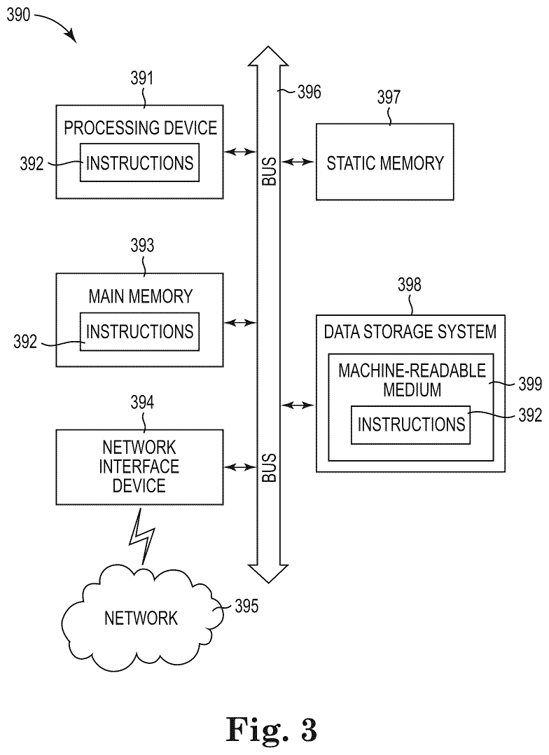

This unique signal is sent to a central control system (such as that shown in FIG. 3) that can make the necessary signal adjustments. Through use of this unique identification process the central control system can make adjustments to the correct photonic device/component.

In some embodiments, the photodetector will detect an envelope of energy on different wavelengths in the communication bus. Whenever it detects these multiple wavelengths passing through the detector it will generate an amount of current based on the desired wavelength being analyzed. If the current is below the threshold, then a spike signal is generated which is used to drive the VCSEL to generate its laser signal which will alert the central control system to a problem with the photonic component identified by that specific wavelength.

The splitter can be designed to split off a small portion (e.g., 5%) of the main signal. In such embodiments, the loss of this small amount of signal strength will not adversely affect the communication of information on the main waveguide photonic signal.

FIG. 3 is a block diagram of an example computer system in which embodiments of the present disclosure may operate. For example, FIG. 3 illustrates an example machine of a computer system 390 within which a set of instructions, for causing the machine to perform any one or more of the methodologies discussed herein, can be executed. Such a computer system can be utilized as the central control system described above.

In some embodiments, the computer system 390 can correspond to a host system that includes, is coupled to, or utilizes a memory sub-system (e.g., the memory sub-systems). The computer system 390 can be used to perform the operations described herein (e.g., to perform operations corresponding to the processor).

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 390 includes a processing device (e.g., processor) 391, a main memory 393 (e.g., read-only memory (ROM), flash memory, dynamic random access memory (DRAM) such as synchronous DRAM (SDRAM) or Rambus DRAM (RDRAM), etc.), a static memory 397 (e.g., flash memory, static random access memory (SRAM), etc.), and a data storage system 398, which communicate with each other via a bus 396.

The processing device 391 represents one or more general-purpose processing devices such as a microprocessor, a central processing unit, or the like. More particularly, the processing device 391 can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 391 can also be one or more special-purpose processing devices such as an application specific integrated circuit (ASIC), a field programmable gate array (FPGA), a digital signal processor (DSP), network processor, or the like. The processing device 391 is configured to execute instructions 392 for performing the operations and steps discussed herein. The computer system 390 can further include a network interface device 394 to communicate over the network 395.

The data storage system 398 can include a machine-readable storage medium 399 (also known as a computer-readable medium) on which is stored one or more sets of instructions 392 or software embodying any one or more of the methodologies or functions described herein. The instructions 392 can also reside, completely or at least partially, within the main memory 393 and/or within the processing device 391 during execution thereof by the computer system 390, the main memory 393 and the processing device 391 also constituting machine-readable storage media. The machine-readable storage medium 399, data storage system 398, and/or main memory 393 can correspond to the memory sub-systems.

In some embodiments, the instructions 392 include instructions to implement functionality corresponding to examples described herein (e.g., using the processor). For example, the processing device 391 can operate a laser sensing component to sense when a signal from a VCSEL has been received and to determine which photonic device/component is having an issue based on the unique identifier signal sent.

While the machine-readable storage medium 399 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although the following description refers to a processing device and a memory device, the description may also apply to a system with multiple processing devices and multiple memory devices. In such examples, the instructions may be distributed across (e.g., stored by) multiple memory devices and the instructions may be distributed across (e.g., executed by) multiple processing devices.

The memory sub-systems may comprise memory devices. The memory devices may be electronic, magnetic, optical, or other physical storage device that stores executable instructions. One or both of the memory devices may be, for example, non-volatile or volatile memory. In some examples, one or both of the memory devices is a non-transitory MRM comprising RAM, an Electrically-Erasable Programmable ROM (EEPROM), a storage drive, an optical disc, and the like. The memory sub-systems may be disposed within a controller, the health monitoring computing device, and/or the devices 103. In this example, the instructions can be “installed” on the health monitoring computing device.

The memory sub-systems can be portable, external or remote storage mediums, for example, that allow the health monitoring computing device and/or the devices 103 to download the instructions from the portable/external/remote storage mediums. In this situation, the instructions may be part of an “installation package.” As described herein, the memory sub-systems can be encoded with executable instructions (e.g., instructions) for monitoring the health of the photonic components and adjustment of operational parameters to improve performance of the system based on the photonics health data from the photonics probing system.

In various examples, the processors can be internal to the memory sub-systems instead of being external to the memory sub-systems. For instance, the processors can be processor in memory (PIM) processors. The processors can be incorporated into the sensing circuitry of the memory sub-systems and/or can be implemented in the periphery of the memory sub-systems, for instance. The processors can be implemented under one or more memory arrays of the memory sub-systems.

One example embodiment that utilizes such devices includes a photonic device management system. The system having a photonic probing system including a communication bus for communicating a main photonic waveguide signal therethrough, a splitter that splits off a portion of the main photonic waveguide signal to create an off-shoot portion photonic signal, a photodetector that converts the off-shoot portion photonic signal to a converted electrical current, a current threshold detector that compares the converted electrical current to a threshold value.

The comparison is used to determine if the converted electrical current exceeds the threshold value. If the converted electrical current does not exceed the threshold value, then the current threshold detector generates a laser generating signal directed toward a VCSEL.

The laser generating signal drives the VCSEL to generate a laser signal. The overall system also includes a central control system including a laser signal receiver that receives the generated laser signal from the photonic probing system.

In some embodiments, the photonic device management system has a central control system that includes a computing device. The computing device includes a processor and memory and can include memory having instructions executable by the processor to: detect the reception of the laser signal from the photonic probing system. The computing device can also include instructions that are executable to identify a particular photonic component or device that the laser signal is indicating has a power output issue.

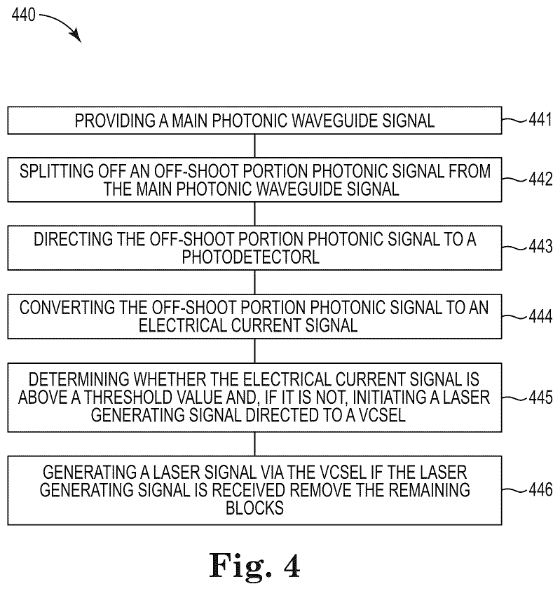

FIG. 4 is a flow diagram corresponding to a method of providing photonic device health monitoring in accordance with some embodiments of the present disclosure. FIG. 4 includes providing a main photonic waveguide signal, at 441. At 442, the method provides splitting off an off-shoot portion photonic signal from the main photonic waveguide signal. The method also includes directing the off-shoot portion photonic signal to a photodetector, at 443. Additionally, at 444, the method provides converting the off-shoot portion photonic signal to an electrical current signal. The method also determines whether the electrical current signal is above a threshold value and, if it is not, initiating a laser generating signal directed to a VCSEL, at 445. And, at 446, includes generating a laser signal via the VCSEL if the laser generating signal is received.

The method 440 may be performed, in some examples, using a computing system and/or a photonic probing system, such as those described with respect to FIGS. 2 and 3.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A photonic probing system, comprising:
a communication bus for communicating a main photonic waveguide signal therethrough;
a splitter that splits off a portion of the main photonic waveguide signal to create an off-shoot portion photonic signal;
a photodetector that converts the off-shoot portion photonic signal to a converted electrical current;
a current threshold detector that compares the converted electrical current to a threshold value to determine if the converted electrical current exceeds the threshold value, if the converted electrical current does not exceed the threshold value, then the current threshold detector generates a laser generating signal directed toward a vertical cavity surface emission laser (VCSEL); and
wherein the laser generating signal drives the VCSEL to generate a laser signal directed toward a central control system.

2. The photonic probing system of claim 1, wherein the splitter can be tuned to split off one or more different wavelengths.

3. The photonic probing system of claim 1, wherein the system further includes a directional coupler.

4. The photonic probing system of claim 3, wherein the directional coupler can be tuned to split off one or more different wavelengths.

5. The photonic probing system of claim 1, wherein the laser generating signal is a spike signal.

6. The photonic probing system of claim 1, wherein the laser signal has a unique identifier known to the central control system.

7. The photonic probing system of claim 1, wherein the main photonic waveguide signal is a signal including multiple wavelengths.

8. The photonic probing system of claim 1, wherein the off-shoot portion photonic signal is a signal including multiple wavelengths.

9. The photonic probing system of claim 1, wherein the main photonic waveguide signal is a signal including multiple wavelengths and the splitter is tuned to split off a portion of the main photonic waveguide signal from a particular photonic device.

10. The photonic probing system of claim 1, wherein the main photonic waveguide signal is a signal including multiple wavelengths and the splitter is tuned to split off a portion of the main photonic waveguide signal containing a wavelength associated with a particular photonic device.

11. A method, comprising:
providing a main photonic waveguide signal;
splitting off an off-shoot portion photonic signal from the main photonic waveguide signal;
directing the off-shoot portion photonic signal to a photodetector;
converting the off-shoot portion photonic signal to an electrical current signal;
determining whether the electrical current signal is above a threshold value and, if it is not, initiating a laser generating signal directed to a vertical cavity surface emission laser (VCSEL); and
generating a laser signal via the VCSEL if the laser generating signal is received.

12. The method of claim 11, wherein the laser signal is unique to a particular wavelength being analyzed by the photonic probing system.

13. The method of claim 11, wherein the laser signal is unique to a particular wavelength from the main photonic waveguide signal.

14. The method of claim 11, wherein the laser signal is unique to a particular wavelength from the off-shoot portion photonic signal.

15. The method of claim 11, wherein the laser signal is unique to a particular wavelength representative of a particular photonic component.

16. The method of claim 11, wherein the laser signal is unique to a particular wavelength representative of a particular photonic device.

17. A photonic device management system, comprising:
a photonic probing system including:
a communication bus for communicating a main photonic waveguide signal therethrough;
a splitter that splits off a portion of the main photonic waveguide signal to create an off-shoot portion photonic signal;
a photodetector that converts the off-shoot portion photonic signal to a converted electrical current;
a current threshold detector that compares the converted electrical current to a threshold value to determine if the converted electrical current exceeds the threshold value, if the converted electrical current does not exceed the threshold value, then the current threshold detector generates a laser generating signal directed toward a VCSEL; and
wherein the laser generating signal drives the VCSEL to generate a laser signal; and
a central control system including a laser signal receiver that receives the generated laser signal from the photonic probing system.

18. The photonic device management system of claim 17, wherein the central control system includes a computing device.

19. The photonic device management system of claim 18, wherein the computing device includes a processor and memory and wherein the memory includes instructions executable by the processor to: detect the reception of the laser signal from the photonic probing system.

20. The photonic device management system of claim 17, wherein the instructions are further executable to identify a particular photonic component or device that the laser signal is indicating has a power output issue.
